(19) United States
(12) Patent Application Publication
(10) Pub. No.: US 2009/0309161 A1
(43) Pub. Date: Dec. 17, 2009

(54) Semiconductor integrated circuit device

(75) Inventor: Hoon Chang, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/457,537

(22) Filed: Jun. 15, 2009

(30) Foreign Application Priority Data
Jun. 16, 2008 (KR) 10-2008-0056391

(51) Int. Cl. H01L 29/78

(52) U.S. Cl. 257/368; 257/E29.255

(57) ABSTRACT

A semiconductor integrated circuit device and a method of fabricating the same for increasing channel length while permitting the channel to remain stable. The semiconductor integrated circuit device includes a semiconductor substrate with lightly-doped impurity regions, a gate stack, and offset spacers. The gate stack includes an insulating layer formed on the semiconductor substrate and a gate electrode formed on the gate insulating layer. The offset spacers are formed of an insulating material having high dielectric constant on both sidewalls of the gate stack.

### CROSS-REFERENCE TO RELATED APPLICATION

This U.S. non-provisional application claims priority under 35 U.S.C. §119 to Korean Patent Application No. 10-2008-0056391 filed on Jun. 16, 2008, the entire contents of which are incorporated herein by reference.

### BACKGROUND

1. Field of the Invention

Example embodiments relate to a semiconductor integrated circuit device (e.g. a semiconductor integrated circuit device having improved reliability).

2. Description of Conventional Art

Increased integration density of semiconductors has led to a decrease in the size of metal-oxide semiconductor (MOS) elements. Likewise, as the size of semiconductor integrated circuit devices decrease, the width of gate electrodes and the length of channels have also decreased.

In some instances, this miniaturization trend has caused channels to become too short, leading to various reliability problems (e.g. short channel effect). In light of such problems, a method of miniaturizing a semiconductor integrated circuit device while simultaneously securing sufficiently long channels may improve the reliability of semiconductor integrated circuit devices.

### SUMMARY

Example embodiments provide a semiconductor integrated circuit device having improved reliability.

According to an example embodiment, a semiconductor integrated circuit device may include a gate stack, offset spacers, and lightly-doped impurity regions. The gate stack may include a gate insulating layer and a gate electrode, with the gate electrode on the gate insulating layer. The offset spacers may be on sidewalls of the gate stack, with the offset spacers having a higher dielectric constant than the gate insulating layer. The lightly-doped impurity regions may be formed in a semiconductor substrate and aligned with the offset spacers.

According to another example embodiment, a semiconductor integrated circuit device may include a gate stack, offset spacers, and insulating spacers. The gate stack may include a gate insulating layer and a gate electrode, with the gate electrode on the gate insulating layer. The offset spacers may be on sidewalls of the gate stack, with the offset spacers formed of a material having a dielectric constant greater than or equal to 25. Also, the insulating spacers may be on the offset spacers, the insulating spacers formed of an insulating material.

### BRIEF DESCRIPTION OF THE FIGURES

The accompanying figures are included to provide a further understanding of example embodiments, and are incorporated in and constitute a part of this specification. In the figures:

FIG. 1 illustrates a cross-sectional view of a semiconductor integrated circuit device according to an example embodiment;

FIGS. 2A through 2C illustrate cross-sectional views illustrating operation of the semiconductor integrated circuit device shown in FIG. 1; and

FIGS. 3 through 9 illustrate cross-sectional views for explaining a method of fabricating a semiconductor integrated circuit device according to an example embodiment.

### DETAILED DESCRIPTION OF THE EXAMPLE EMBODIMENTS

Example embodiments may be embodied in many different forms and should not be construed as being limited to the embodiments set forth herein; rather, these embodiments may be provided so that this disclosure will be thorough and complete, and will fully convey the concept of example embodiments to those skilled in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

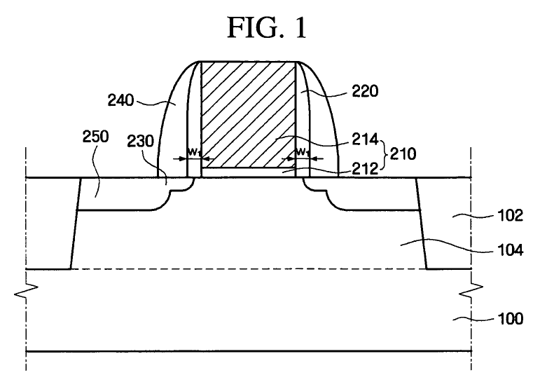

FIG. 1 illustrates a cross-sectional view of a semiconductor integrated circuit device according to an example embodiment. The semiconductor integrated circuit device includes a gate stack 210, offset spacers 220, lightly-doped impurity regions 230, insulating spacers 240 and heavily-doped impurity regions 250. A gate insulating layer 212 and a gate electrode 214 are sequentially formed on a semiconductor substrate, forming the gate stack 210.

The semiconductor substrate 100 may be a silicon substrate, a silicon-on-insulator (SOI) substrate, a gallium arsenide substrate, a silicon germanium substrate, a ceramic substrate, a quartz substrate or a glass substrate for use in a display device. The semiconductor substrate 100 may be a P-type substrate. Alternatively, a P-type epitaxial layer may be grown on the semiconductor substrate 100.

The semiconductor substrate 100 is divided into an active region 104 and an isolation region 102. The active region 104 is in the semiconductor substrate 100, and is defined by isolation region 102. The isolation region 102 may be shallow trench isolations (STI) or field oxide (FOX) films. A transistor is formed in the active region. The gate stack 210, in which the gate insulating layer 212 and the gate electrode 214 are sequentially stacked.

The gate insulating layer 212 may be a silicon oxide (SiOx) layer or a silicon oxynitride (SiON) layer. The thickness of the gate insulating layer 212 may vary according to the type of the semiconductor integrated circuit device. For example, the thickness of the gate insulating layer 212 may be 10-15 Å.

The gate electrode 214 is formed on the gate insulating layer 212. The gate electrode 214 may be formed of a conductive material such as polysilicon. Alternatively, the gate electrode 214 may be formed by sequentially depositing polysilicon and a metal on the gate insulating layer 212. The metal may be W, Al or TiN.

The offset spacers 220 are formed on both sidewalls of the gate stack 210. The offset spacers 220 may be formed of a high dielectric material. A high dielectric material is a material with a high dielectric constant. A high dielectric constant may be a dielectric constant greater than or equal to 25. Also, a high dielectric constant may be a dielectric constant greater than the dielectric constant of an adjacent material. In particular, the offset spacers 220 may have a higher dielectric constant than the gate insulating layer 212. For example, the offset spacers 220 may be formed of an oxide of at least one selected from Hf; Al, Zr, Ta and Ti. Specifically, the offset spacers 220 may be formed of HfO₂, HfAlO, HfSiO, ZrO₂, Ta₂O₅, TiO₂ or a combination thereof. A width W₁ of the offset spacers 220 may be 30-200 Å. The width W₁ is the horizontal length of the portions of the offset spacers 220 that directly contact the semiconductor substrate 100 (e.g. the longest distance between the gate stack 210 and the insulating spacers 240). The width W₁ may be empirically determined based on a desired channel length and a width W₂ of the gate stack 210.

The lightly-doped impurity regions 230 may be formed in the semiconductor substrate 100 and may be aligned with the offset spacers 220. Alternatively, the lightly-doped impurity regions 230 may be formed so as to partially overlap with portions of the semiconductor substrate 100 directly below by the offset spacers 220. For example, the lightly-doped impurity regions 230 may be formed by implanting impurity ions into the semiconductor substrate 100 using the offset spacers 220 as masks. During the implantation of impurity ions into the semiconductor substrate 100, impurity ions may be implanted into the portions of the semiconductor substrate 100 directly below the offset spacers 220 by, for example, (1) adjusting the angle of the implantation of impurity ions, or (2) dispersing impurity ions into the portions of the semiconductor substrate 100 directly below the offset spacers 220. Here, dispersing impurity ions may be because of natural diffusion in the manufacturing process, or may be because of additional annealing process.

This may permit the lightly-doped impurity regions 230 to extend to the portions of the semiconductor substrate 100 directly below the offset spacers 220.

The formed transistor may be either a P-type transistor or an N-type transistor. To form a P-type transistor, the lightly-doped impurity regions 230 may be formed of P-type impurities such as boron (B), boron fluoride (BF₂ or BF₃), or indium (In). On the other hand, to form an N-type transistor, the lightly-doped impurity regions 230 may be formed of N-type impurities such as phosphor (P) or asbestos (As).

The insulating spacers 240 are formed on the offset spacers 220. The width of insulating spacers 240 may be larger than that of the offset spacers 220, and the insulating spacers 240 may be formed of SiN.

The heavily-doped impurity regions 250 may be formed in the semiconductor substrate 100 and may be aligned with the insulating spacers 240. The heavily-doped impurity regions 250 may have a higher impurity concentration than the lightly-doped impurity regions 230 and may be doped at a greater depth in the semiconductor substrate 100 than the lightly-doped impurity regions 230.

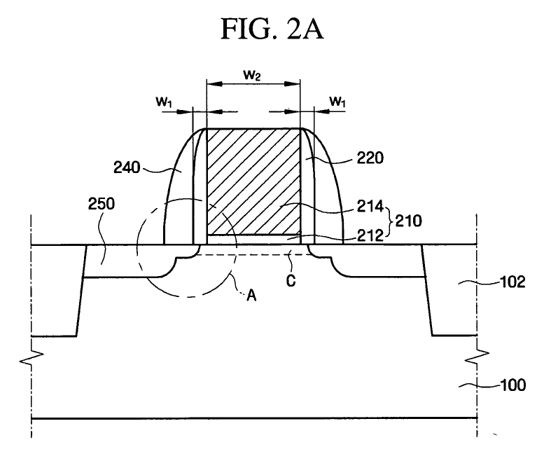

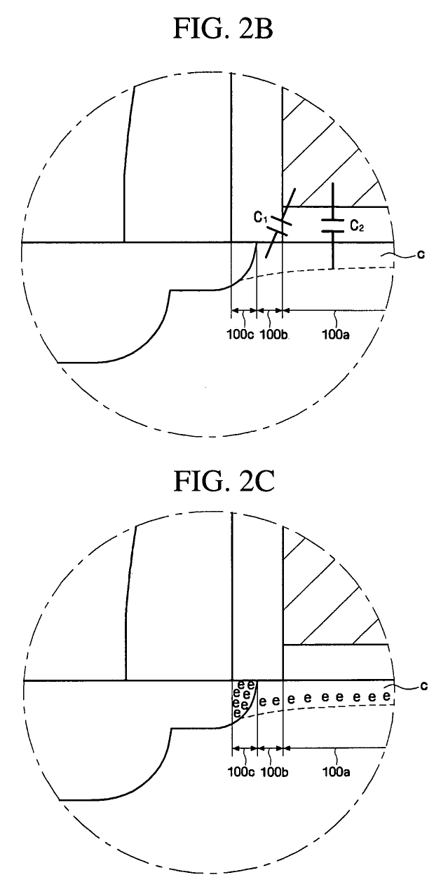

FIGS. 2A through 2C illustrate cross-sectional views explaining the operation of the semiconductor integrated circuit device shown in FIG. 1 according to an example embodiment. FIG. 2A illustrates a cross-sectional view of a channel region of the semiconductor integrated circuit device in which the transistor is an N-type transistor. Accordingly, electrons are used as carriers in said illustration. However, the semiconductor integrated circuit device can also be formed to be a P-type transistor, which uses holes as carriers. FIGS. 2B and 2C illustrate enlarged views of portion A in FIG. 2A.

The offset spacers 220 are formed on both sidewalls of the gate electrode 210. The channel C may be formed below the offset spacers 220. In general, the length of a channel is almost the same as the width of the gate stack 210, which may be W₂. However, the widths of the offset spacers 220 may increase the length of the channel C formed in the semiconductor substrate 100. In FIG. 2A, the offset spacers 220 have a width W₁, thereby increasing the length of the channel C to 2W₁+W₂.

Regarding FIG. 2B, applying a voltage higher than a threshold voltage to the gate electrode 214 causes the channel C to be formed in a portion 100a of the semiconductor substrate 100. Channel C is below the gate insulating layer 212. Due to the difference between the voltage of the semiconductor substrate 100 and the voltage of the gate electrode 214, the gate insulating layer 212 has a capacitance C₂.

The offset spacers 220, which are formed of an insulating material having high dielectric constant, have a capacitance C₁ which is between the gate electrode 214 and portion 100b of the semiconductor substrate 100. In the case where the spacers are formed of an insulated material, not a material with a high dielectric, the capacitance between the gate electrode 214 and the lower portion of the offset spacer is very low. However, according to an example embodiment of present invention, the offset spacers 220 in the semiconductor integrated circuit device are formed of a material with a high dielectric constant. Also, offset spacers 220 may have a higher dielectric constant than the gate insulating layer 212. In particular, the offset spacers 220 may have a dielectric constant greater than or equal to 25. Due to the high dielectric constant of the offset spacers 220, the capacitance C₁ is instead very high.

The gate insulating layer 212 may be formed of SiO₂, which has a dielectric constant of 3.9 and a thickness of 30 Å, and that the offset spacers 220 may be formed of HfO₂, which has a width of 80 Å. In addition, the distance between the gate electrode 214 and the portion 100b may be 120 Å, such that when a voltage is applied to the gate electrode 214, voltage may diagonally pass through one of the offset spacers 220 into portion 100b.

Also, the gate insulating layer 212 has a capacitance which is between the gate electrode 214 and portion 100a of the semiconductor substrate 100. The capacitance of the gate insulating layer 212 is both (a) proportional to the dielectric constant of the gate insulating layer 212, and (2) inversely proportional to the thickness of the gate insulating layer 212. Since the gate insulating layer 212 is made of an insulating material and may also be physically thin, the capacitance C₂ is lower than the capacitance C₁. Thus, offset spacers 220 require a higher voltage than to the gate insulating layer 212. This permits electrons to gather even in portion 100b, such that the channel that include portion 100a extends to portion 100b.

If the lightly-doped impurity regions 230 extend directly below the offset spacers 220, it is possible for more electrons to gather in portion 100c than in portion 100b due to carriers in the offset spacers 220, as illustrated in FIG. 2C. Thus, it is possible to form a stable channel C which may properly connect the lightly-doped impurity regions 230.

Forming off-set spacers 220 from an insulating material having high dielectric constant makes it possible to form a stable channel C between the lightly doped impurity regions 230 on both sidewalls of the gate stack 210 regardless of the width of the offset spacers 220. Thus, forming the offset spacers 220 to a certain width permits a stable channel of a desired length to form.

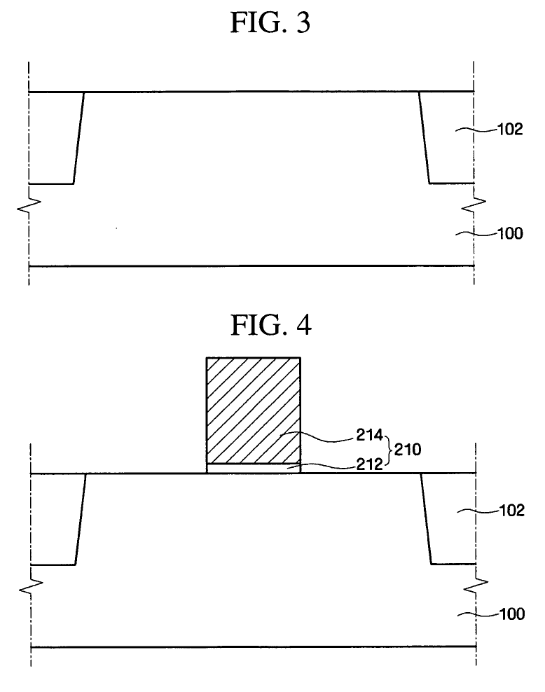

A semiconductor integrated circuit device according to an example embodiment, such as that illustrated in FIG. 1, may be fabricated. A method of fabricating semiconductor integrated circuit device is illustrated in FIGS. 3 through 8. FIGS. 3 through 8 illustrate cross-sectional views explaining steps in a method of fabricating a semiconductor integrated circuit device according to an example embodiment.

In FIG. 3, a semiconductor substrate 100 is prepared. Isolation regions 102 are formed in the semiconductor substrate 100, thereby defining an active region in between. The isolation regions 102 may be FOX isolations obtained by a local oxidation of silicon (LOCOS) method or may be STIs.

Thereafter, in FIG. 4, a gate stack 210 is formed on the semiconductor substrate 100 by sequentially depositing a gate insulating layer 212 and a gate electrode 214 on the semiconductor substrate 100. The gate insulating layer 212 may be formed on the semiconductor substrate 100 by performing an oxidation operation. Thereafter, the gate electrode 214 is formed by depositing a conductive material on the gate insulating layer 212. Thereafter, a mask pattern (not shown) may be formed by performing photolithography on the gate electrode 214. After that, the gate insulating layer 212 and the gate electrode 214 may be patterned using the mask pattern as an etching mask, thereby completing formation of the gate stack 210.

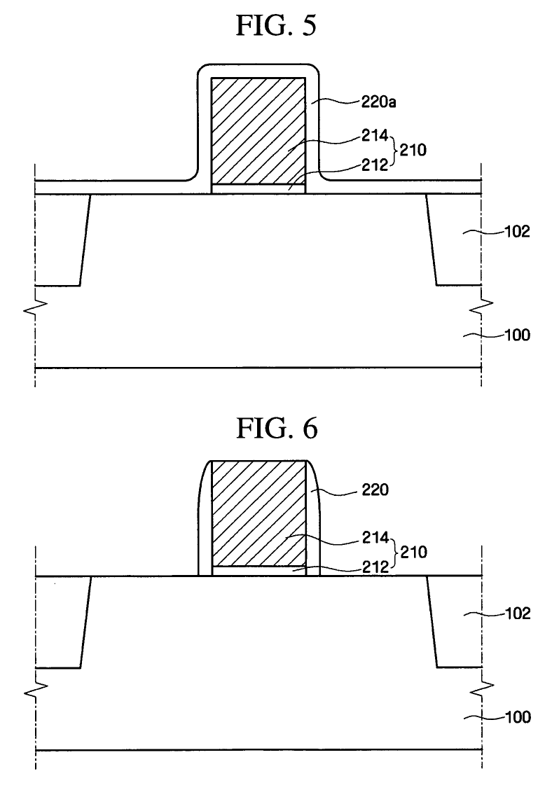

Next, an insulating material having high dielectric constant layer 220a is formed on the semiconductor substrate 100 on which the gate stack 210 is formed, as illustrated in FIG. 5. The insulating material having high dielectric constant layer 220a may be formed using chemical mechanical deposition (CVD) or atomic layer deposition (ALD). The insulating material having high dielectric constant layer 220a may be formed of an oxide of at least one selected from Hf, Al, Zr, Ta and Ti. For example, the insulating material having high dielectric constant layer 220a may be formed of HfO₂, HfAlO, HfSiO, ZrO₂, Ta₂O₅, TiO₂ or a combination thereof. The thickness of the insulating material having high dielectric constant layer 220a may be about 30-400 Å.

In FIG. 6, offset spacers 220 are formed on both sidewalls of the gate stack 210 by performing anisotropic etching on the insulating material having high dielectric constant layer 220a. The offset spacers 220 may have a higher dielectric constant than the gate insulating layer 212. This makes it possible to stably form a channel region in the semiconductor substrate 100 below the offset spacers 220 while securing a sufficient channel length.

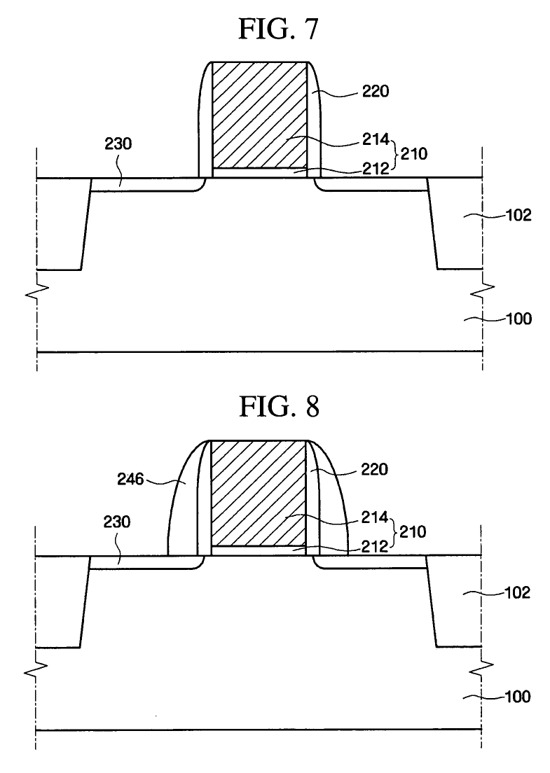

Thereafter, in FIG. 7, lightly-doped impurity regions 230 are formed in the semiconductor substrate 100 by implanting impurity ions into the semiconductor substrate 100 using the gate stack 210 and the offset spacers 220 as a mask. The lightly-doped impurity regions 230 are formed by implanting impurity ions having a predetermined conductivity type. If a transistor to be formed is a P-type transistor, the lightly-doped impurity regions 230 may be formed by implanting P-type impurity ions. P-type impurity ions may include boron (B), boron fluoride (BF₂ or BF₃), or indium (In). On the other hand, if the transistor to be formed is an N-type transistor, the lightly-doped impurity regions 230 may be formed by implanting N-type impurity ions. The N-type impurity ions may include phosphor (P) or asbestos (As).

The lightly-doped impurity regions 230 may be aligned with the outer surfaces of the offset spacers 220 by implanting impurity ions into the semiconductor substrate 100 using the gate stack 210 and the offset spacers 220 as a mask. Alternatively, the lightly-doped impurity regions 230 may be tilted or may be formed even below the offset spacers 220 by adjusting the angle of implantation of impurity ions.

Next, insulating spacers 240 are formed on the offset spacers 220, as illustrated in FIG. 8. The insulating spacers 240 may be formed by having an insulating layer on the entire surface of the semiconductor substrate 100 and performing anisotropic etching on the insulating layer. The insulating spacers 240 may include a nitride layer.

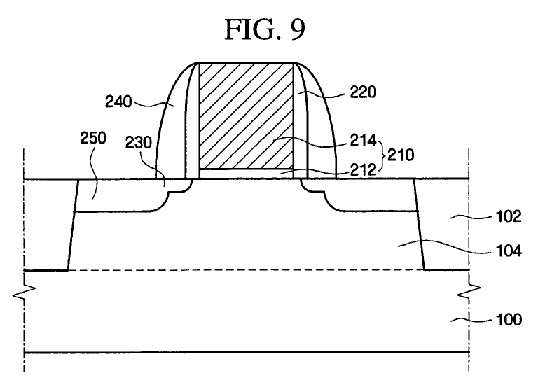

Finally, in FIG. 9, heavily-doped impurity regions 250 are formed in the semiconductor substrate 10 by implanting impurity ions into the semiconductor substrate 100 using the gate stack 210 and the insulating spacers 240 as a mask. The heavily-doped impurity regions 250 may be formed to a greater depth than the lightly-doped impurity regions 230. If the transistor to be formed is a P-type transistor, the heavily-doped impurity regions 250 may be formed by implanting P-type impurity ions. The P-type impurity ions may be boron (B), boron fluoride (BF₂ or BF₃), or indium (In). On the other hand, if the transistor to be formed is an N-type transistor, the heavily-doped impurity regions 250 may be formed by implanting N-type impurity ions. The N-type impurity ions may be phosphor (P) or asbestos (As).

What is claimed is:

1. A semiconductor integrated circuit device comprising:
a gate stack including a gate insulating layer and a gate electrode, the gate electrode on the gate insulating layer;
offset spacers on sidewalls of the gate stack, the offset spacers having a higher dielectric constant than the gate insulating layer; and
lightly-doped impurity regions formed in a semiconductor substrate and aligned with the offset spacers.

2. The semiconductor integrated circuit device of claim 1, wherein the offset spacers include an oxide layer.

3. The semiconductor integrated circuit device of claim 2, wherein the oxide layer comprises at least one of HfO₂, HfAlO, HfSiO, ZrO₂, Ta₂O₅, TiO₂, and a combination thereof.

4. The semiconductor integrated circuit device of claim 2, wherein the oxide layer is an oxide of at least one of Hf, Al, Zr, Ta and Ti.

5. The semiconductor integrated circuit device of claim 1, wherein the offset spacers have a dielectric constant greater than or equal to 25.

6. The semiconductor integrated circuit device of claim 1, further comprising insulating spacers formed on the offset spacers.

7. The semiconductor integrated circuit device of claim 6, wherein the insulating spacers are formed of SiN.

8. The semiconductor integrated circuit device of claim 6, wherein the width of insulating spacers is larger than that of the offset spacers.

9. The semiconductor integrated circuit device of claim 1, wherein the gate stack is on the semiconductor substrate.

10. The semiconductor integrated circuit device of claim 9, wherein the lightly-doped impurity regions partially overlap with portions of the semiconductor substrate directly below the offset spacers.

11. The semiconductor integrated circuit device of claim 10, wherein a channel in the semiconductor substrate below the gate insulating layer permits a concentration of carriers in portions of the lightly-doped regions to overlap with the portions of the semiconductor substrate directly below the offset spacers.

12. The semiconductor integrated circuit device of claim 10, wherein when a channel is formed in the semiconductor substrate below the gate insulating layer, the channel extends to portions of the semiconductor substrate directly below the offset spacers.

13. The semiconductor integrated circuit device of claim 6, further comprising:
heavily-doped impurity regions formed in the semiconductor substrate and aligned with the insulating spacers.

14. The semiconductor integrated circuit device of claim 1, wherein the thickness of the gate insulating layer is between 10-15 Å.

15. The semiconductor integrated circuit device of claim 1, wherein width of the offset spacers is between 30-200 Å

16. The semiconductor integrated circuit device of claim 1, wherein the lightly-doped impurity region comprises at least one of B, BF₂, BF₃, and In.

17. The semiconductor integrated circuit device of claim 1, wherein the lightly-doped impurity region comprises at least one of P and As.

18. A semiconductor integrated circuit device comprising:
a gate stack including a gate insulating layer and a gate electrode, the gate electrode on the gate insulating layer;
offset spacers on sidewalls of the gate stack, the offset spacers formed of a material having a dielectric constant greater than or equal to 25; and
insulating spacers on the offset spacers, the insulating spacers formed of an insulating material.

19. The semiconductor integrated circuit device of claim 18, wherein the offset spacers include an oxide layer.

20. The semiconductor integrated circuit device of claim 19, wherein the oxide layer is an oxide of at least one of Hf, Al, Zr, Ta and Ti.
